(19) United States
(12) Patent Application Publication
(10) Pub. No.: US 2015/0322586 A1
(43) Pub. Date: Nov. 12, 2015

(54) BONDING WIRE AND PROCESS FOR MANUFACTURING A BONDING WIRE

(71) Applicant: MICROBONDS INC., Markham (CA)

(72) Inventors: Robert LYN, Markham (CA); John I. PERSIC, Toronto (CA)

(21) Appl. No.: 14/360,644

(22) PCT Filed: Nov. 20, 2012
(86) PCT No.: PCT/IB2012/002403

§ 371 Date: May 26, 2014

(30) Foreign Application Priority Data
Nov. 26, 2011 (EP) 11 400 056.5

(51) Int. Cl. C25D 7/06; C25D 3/50; C25D 3/54; C23C 14/34; C23C 18/31; B32B 15/01; C23C 4/08; C23C 18/16; H01B 5/02; H01B 1/02; B32B 1/00; C25D 3/48; C23C 4/12

(52) U.S. Cl. CPC C25D 7/0607; C25D 3/48; C25D 3/50; C25D 3/54; C23C 14/34; C23C 18/31; C23C 4/12; C23C 4/08; C23C 18/1633; H01B 5/02; H01B 1/026; H01B 1/02; B32B 1/00; B32B 15/018; B32B 15/01

(57) ABSTRACT

A bonding wire comprises a core wire generally made of silver or a silver alloy, and the coating material is selected from one or more of: gold, palladium, platinum, rhodium. Alternatively, the core wire is generally made of copper or a copper alloy, and the coating material is selected from one or more of: palladium, platinum, rhodium, iridium, ruthenium. For both core wires, the coating material can be selected from a group of materials with the following characteristics: (1) the materials' melting temperature is higher than the melting temperature of the core wire material, respectively; (2) the materials' molten surface tension is higher than that of the core wire material, respectively; (3) the materials show a high resistance to oxide formation between the melting temperature of the core wire material and the melting temperature of the respective material itself; and (4) the coating material has the additional characteristic that the material's melting temperature is lower than the boiling temperature of the core wire material.

### TECHNICAL FIELD

The present invention relates to a bonding wire. Moreover, the present invention relates to a composite bonding wire. Still further, the present invention relates to a composite silver bonding wire. Still further, the present invention relates to a composite copper bonding wire. The present invention also relates to a process for manufacturing a bonding wire.

### DESCRIPTION OF THE RELATED ART

The increasing global demand for electronics is driving the need for greater performance capabilities of semiconductor chips at lower cost. Currently, the majority of semiconductor chips are internally connected using a thin gold bonding wire. With the rise in the market price for gold metal, the cost of using gold as a bonding wire material has become economically prohibitive. Users have been seeking to replace gold wire with alternative low-cost metals such as copper, aluminium and silver wires, with limited success due to fundamental technical limitations.

Copper wire is the current choice as the replacement for gold wire, as it is cheap and has high conductivity. However, copper wire is much harder than gold wire and has the possibility of damaging sensitive chip structures. Copper wire also oxidizes, it is unstable over time with inconsistent results in wire-bonding.

Furthermore, it has been observed that the point of contact where the bonded ball of the copper wire connects to the aluminium bonding pad of an IC (integrated circuits) chip is subject to high risk of accelerated galvanic corrosion and erosion of the aluminium pad.

Palladium coated copper wires, fabricated using an electroplated palladium layer on top of the copper wire, have recently been proposed as a potential solution to the oxidation of the copper wire surface and alleviation of the galvanic corrosion concerns; however, palladium is a harder material than copper, and further increases the hardness. Also importantly, current palladium coated copper wires suffer from negative issues related to consistent thickness, distribution and morphology of the palladium on the wire. This inconsistency results in problems with free air ball formation (FAB), including inconsistent spherical and axi-symmetric free air ball (FAB) formation and insufficient coverage of palladium on the free air ball (FAB).

### SUMMARY

In contrast thereto, the invention provides a bonding wire with the features of claims 1, 2, 3, and 4, respectively, as well as a process for manufacturing a bonding wire with the features of claims 10, 11, 12, and 13, respectively.

A bonding wire as provided presently comprises a core wire, the core wire generally being made of silver or a silver alloy. The core wire is generally surrounded by a coating material.

According to an aspect of the invention, the coating material is selected from one or more of: gold, palladium, platinum, rhodium.

Alternatively, a bonding wire as provided presently comprises a core wire, the core wire generally being made of copper or a copper alloy. The core wire is generally surrounded by a coating material.

According to an aspect of the invention, the coating material is selected from one or more of: palladium, platinum, rhodium, iridium, ruthenium.

According to another aspect of the invention, the coating material for a core wire to create a bonding wire is selected from a group of materials with the following characteristics: (1) the materials' melting temperature is higher than the melting temperature of the core wire material (i.e. silver or silver alloy or copper or copper alloy), respectively; (2) the materials' molten surface tension is higher than that of the core wire material, respectively; (3) the materials show a high resistance to oxide formation between the melting temperature of the core wire material and the melting temperature of the respective material itself; (4) the materials' melting temperature is lower than the boiling temperature of the core wire material.

The inventors have realized that the use of silver or a silver-alloy or copper or copper alloy as a core wire material leads to an ideal low-cost replacement for gold bonding wire in the bonding of integrated circuits.

Considering silver based wire as a core bonding wire material, silver has the highest electrical conductivity of all metals and it does not easily oxidize at room temperature. Furthermore, it is soft and malleable which enables stable ultrasonic welding to chips using a standard process known as wire-bonding, without the potential for damage to chips. However, silver wire has an intrinsic technical limitation, which is the inability to form a free air ball (FAB) required for wire-bonding, without the use of a special shielding gas (such as pure nitrogen).

Considering copper based wire as a core bonding wire material, it is noted that palladium coated copper wires have been discussed; however, they suffer from issues related to poor free air ball formation (FAB), high bonded ball hardness, and insufficient coverage of palladium on the free air ball (FAB) surface, resulting in performance and reliability issues.

Therefore, an objective of the present invention is to provide an improved composite silver bonding wire which can form a free air ball for wire-bonding under standard atmospheric conditions (i.e. normal air, without the assistance of shielding gas such as nitrogen).

Another objective of the present invention is to provide an improved silver bonding wire which has similar overall wire bonding characteristics as gold bonding wire.

Yet another objective of the present invention is to provide an improved composite copper bonding wire which can form a softer bonded ball with uniform distribution of the coating material on the free air ball and bonded ball surface.

These objectives are met by a silver or silver alloy bonding wire coated with a thin material. The coating material can be a noble metal. The coating is made at such thickness, coating process and thermal processing conditions to enable robust formation of a free air ball. Noble metals can be used. Also, other materials than noble metals can be incorporated into composite materials or alloys can be used as coating material.

These objectives are further met by a copper or copper alloy bonding wire coated with a thin material. The coating material can be a noble metal. The coating is made at such thickness, coating process and thermal processing conditions to enable robust formation of a free air ball. Noble metals can be used. Also, other materials than noble metals can be incorporated into composite materials or alloys can be used as coating material.

During the wire bonding cycle for so-called ball bonding, the wire is threaded through the capillary of the feeding device. The next critical step involves creating a free air ball (FAB) using an electrical flame off (EFO). This involves creating an electrical arc between the discharge ‘wand’ and transmitting a high voltage spark across a gap to the tip of the bonding wire, which is at a different potential. The heat generated from the electrical discharge melts the tip of the wire. When gold wire is used as the bonding wire, the metal melts to become a molten liquid ball, due to the upward and surrounding forces exerted by the molten surface tension of gold in air being greater than the force of grayity pulling the molten gold downwards. Hence the molten surface tension and melting temperature are important material properties for ball formation. It is also observed that when there is contamination present on the molten ball, this can also disrupt the formation of the ball and result in off-centered (non axi-symmetric) or malformed (golf club, pointed tip, etc. . . . ) free air balls.

It was found by the inventors that the desired characteristics of a coating material for silver wire free air ball formation in air are: (1) higher melting point than pure silver melting point, (2) higher molten surface tension than pure silver, (3) resistance to oxide formation, and (4) lower melting point than the boiling point of pure silver.

It was also found by the inventors that the desired characteristics of a coating material for copper wire free air ball formation in air are: (1) higher melting point than pure copper melting point, (2) higher molten surface tension than pure copper, (3) resistance to oxide formation, and (4) lower melting point than the boiling point of pure copper.

It should also be noted that although the materials tested and mentioned below are metals, it would be possible for non-metals to be used and combinations thereof.

As mentioned above, the molten surface tension of the coating material is an important characteristic for spherical free air ball formation.

Table 1 below lists selected materials considered to be candidates for the coating material which surrounds the silver wire, comparing their thermophysical properties. An asterisk denotes noble metals. In the first row the characteristics of Ag (silver) are given. Bold characters denote positive, i.e. favorable values and materials.

TABLE 1

| | | | Oxidiz- | Oxide | |
|---|---|---|---|---|---|
| | Melting | | ation | burn-off | Melting |
| | Point | Surface | Temp | at Ag | Point < |
| Pure | (deg. | Tension | (deg. | melting | Ag BP |
| metal | ° C.) | (mN/m) | ° C.) | temp | 2163° C. |
| Ag* | 961 | 910 | <280 C. (>280 C. | NA | 961 |
| | | (N2), <500 | silver oxide | | |
| | | (air) | converts | | |
| | | | to silver) | | |
| Au* | 1063 | 1138 | No oxide | No oxide | Yes |
| Pd* | 1552 | 1500 | 800 | Yes | Yes |
| Pt* | 1770 | 1780 | No oxide | No oxide | Yes |
| Ir* | 2466 | 2250 | No oxide | No oxide | No |
| Os* | 3025 | 2500 | No oxide | No oxide | No |
| Rh* | 1965 | 2000 | No oxide | No oxide | Yes |
| Ru* | 2334 | 2250 | No oxide | No oxide | No |
| Zn | 420 | 815 | Room temp | No | Yes |
| Ni | 1453 | 1725 | 400 | No | Yes |
| Al | 660 | 1007 | Room temp | No | Yes |

Table 2 below lists selected materials considered to be candidates for the coating material which surrounds the copper wire, comparing their thermophysical properties. An asterisk denotes noble metals. In the first row the characteristics of Cu (copper) are given. Bold characters denote positive, i.e. favorable values and materials.

TABLE 2

| | | | Oxidiz- | Oxide | |
|---|---|---|---|---|---|
| | Melting | | ation | burn-off | Melting |
| | Point | Surface | Temp | at Cu | Point < |
| Pure | (deg. | Tension | (deg. | melting | Cu BP |
| metal | ° C.) | (mN/m) | ° C.) | temp | 2163° C. |
| Cu | 1084 | 1355 | | | |
| Au* | 1063 | 1138 | No oxide | No oxide | Yes |
| Pd* | 1552 | 1500 | 800 | Yes | Yes |
| Pt* | 1770 | 1780 | No oxide | No oxide | Yes |
| Ir* | 2466 | 2250 | No oxide | No oxide | Yes |
| Os* | 3025 | 2500 | No oxide | No oxide | No |
| Rh* | 1965 | 2000 | No oxide | No oxide | Yes |
| Ru* | 2334 | 2250 | No oxide | No oxide | Yes |
| Zn | 420 | 815 | Room temp | No | Yes |
| Ni | 1453 | 1725 | 400 | No | Yes |
| Al | 660 | 1007 | Room temp | No | Yes |

Discussion of Molten Surface Tension

Firstly, regarding pure silver, it can be explained why good silver ball formation cannot be made in air. The surface tension of silver in nitrogen gas (910 mN/m) is the lowest of the noble metals and slightly lower than gold (1138 mN/m). However, silver is about one-half the density of gold, so the surface tension should be adequate to exert forces on the molten silver to allow it to form a ball. However, in an air environment, molten silver has a unique property and can absorb 500 times the amount of oxygen than solid silver metal. This has the effect of seriously disrupting and lowering the molten surface tension during ball formation. Thus, the effective surface tension of molten silver in air is estimated to be less than 500 mN/m. To offset this dramatic lowering of surface tension, a suitable coating material is selected to have as high a surface tension as possible. A coating material such as zinc is not desired, while gold, palladium, copper, nickel and aluminium meet this condition of higher surface tension.

Regarding coated copper wire, it can be seen that all materials in the table except gold, zinc and aluminium meet the higher molten surface tension criteria.

Discussion of Melting Point (Minimum & Maximum)

In the case of coated silver wire, the melting point (MP) of the coating material should be higher than the melting point of silver (961° C.). If the material melts too early, it has the possibility of spreading or ‘wicking’ up the wire during ball formation, with not enough material left in the region of the ball. Thus a coating material such as aluminium or zinc is not desired, while palladium, nickel, gold and the like meet this condition.

However, it is also noted that the melting point of the coating material must also be lower than the boiling point (BP) of silver (2163° C.); because when silver reaches the boiling point, the surface will bubble and the resultant surface tension is disrupted. Hence high melting point materials, such as: Osmium, Iridium and Ruthenium have melting points which exceed the boiling point of silver, and are not suitable as a coating material for silver wire.

In the case of coated copper (MP=1086° C., BP=2562° C.) wire, it can be observed that palladium, platinum, iridium, rhodium, ruthenium and nickel meet the criteria of melting point in the desired range.

Discussion of Oxide/Contaminant during FAB formation

It is found that the formation of a ball from a melted wire is a sensitive process and when contaminants, such as oxides or solid residues are present when the silver or copper wire is in the molten state, this has the effect of disrupting the surface. This prevents the formation of a perfect sphere and the results are malformed and/or off-centered balls. Thus a noble metal is a good choice as the coating material. In particular, for silver wire palladium and gold are metals among commonly available materials which can be coated readily. Gold does not form an oxide even at elevated temperature. Palladium will briefly form an oxide at ˜800° C., however, it converts back to pure palladium at the melting point of silver (961° C.) or copper (1084° C.) and beyond. Materials such as nickel and copper exhibit good surface tension and melting point properties but are not ideal as coating materials because they form an oxide which is present on the ball at the respective melting points. Hence, suitable coating materials do not form an oxide at temperatures between the melting points of silver or copper, respectively, and the melting point of the coating material itself.

Thus for coated silver bonding wire, palladium and gold as well as platinum and rhodium are suitable coating materials of the current invention (cf. above table). For coated copper wire, iridium and ruthenium have melting points within the desired range and thus are suitable coating materials of the current invention (cf. again above table).

Other noble metals of high surface tension can also be employed, using the same methodology as described above, however with drawbacks regarding the melting point requirement. It was found in fact that coating materials with a melting temperature higher than the boiling temperature of the core wire material are not feasible because when such a coating material melts, the core material surface would be boiling and bubbling into metal vapour, resulting in an unstable core material-tocoating material interface which again leads to deformed balls.

Discussion of Coating Thickness and Diffusion

It is appreciated that for the coating material to provide the function of improving the consistent performance of free air ball (FAB) of copper or silver wire, the coating material itself must be of consistent thickness and remain on the ball during the free air ball (FAB) formation process.

It was found that a particular type of coating method, using nano-metallic and organic-metallic precursors in liquid solvent, applied to copper wires in solvent was superior to coating fabricated using the electroplated coating method, in terms of providing a consistency in coating thickness and diffusion-free coating layer remaining on the free air ball.

The core wire may have an overall diameter of between 10 μm and 100 μm.

The thickness of the coating material may vary between 10 nm and 500 nm.

The weight percentage of the coating material may be between 0.5% and 4% of the total bonding wire, or the ratio of coating material to core wire material may range from 1 to 4.0 wt % or from 0.5 to 3.0 wt % or from 1 to 3 wt %.

With the invention, very small deviations of coating thickness can be achieved. Further, it has been observed that very little diffusion between the coating material and the core wire material, particularly in the case of palladium coated copper, takes place. Finally, coatings according to the invention are found to contain voids with very little diameter, i.e. an average diameter of less than 100 nm, and thus very little porosity.

Further features and embodiments will become apparent from the description and the accompanying drawings.

It will be understood that the features mentioned above and those described hereinafter can be used not only in the combination specified but also in other combinations or on their own, without departing from the scope of the present disclosure.

Various implementations are schematically illustrated in the drawings by means of an embodiment by way of example and are hereinafter explained in detail with reference to the drawings. It is understood that the description is in no way limiting on the scope of the present disclosure and is merely an illustration of a preferred embodiment.

### BRIEF DESCRIPTION OF THE DRAWINGS

In the drawings,

FIG. 1 shows the result of a FAB (free air ball) formation of an uncoated gold wire in air.

FIG. 2 shows the result of a FAB formation of an uncoated silver wire in air.

FIG. 3 shows the result of a FAB formation of an uncoated silver wire in nitrogen gas.

FIG. 4 shows the result of a FAB formation of a first palladium coated silver wire according to the invention in air.

FIG. 5 shows the result of a FAB formation of a second palladium coated silver wire according to the invention in air.

FIG. 6 shows a stitch pull diagram of the second palladium coated silver wire according to the invention vs. a bare gold wire.

FIG. 7 shows a ball shear diagram of the second palladium coated silver wire according to the invention vs. a bare gold wire.

FIG. 8 shows a cross-section of a typical Pd electroplated copper wire with palladium thickness ranging from about 100 nm to 20 nm.

FIG. 9 shows a consistent Pd coating using thermal decomposition, ranging from about 30 nm to 40 nm.

FIG. 10 shows in closer detail the surface of the electroplated Pd coated copper wire

FIG. 11 shows macro and nano-porous voids in Pd-coated copper by thermal decomposition method.

FIG. 12 shows a void layer observed between copper and Pd coating layer core copper wire surface.

FIG. 13 shows a free air ball (FAB) of electroplated and drawn palladium on copper wire in nitrogen gas.

FIG. 14 shows a free air ball (FAB) of Pd—Cu wire in nitrogen gas, fabricated using organic-metallic thermal decomposition method.

FIG. 15 shows inconsistent electroplated Pd coverage on the bonded ball.

FIG. 16 shows a Pd layer by thermal decomposition uniform coverage of bonded ball.

FIG. 17 shows a diagram depicting the deformability (softness) of Pd—Cu FAB vs bare Cu wire.

FIG. 18 shows a table illustrating the bonded ball height of the electroplated Pd—Cu wire vs. thermal decomposition coated Pd—Cu wire.

FIG. 19 shows a diagram depicting the stitch bond pull strengths for Pd—Cu and bare Cu bonding wires.

FIG. 20 shows a table illustrating the stitch bond pull strength for Pd—Cu coated and bare Cu bonding wires.

### DETAILED DESCRIPTION

Coated Silver Wire

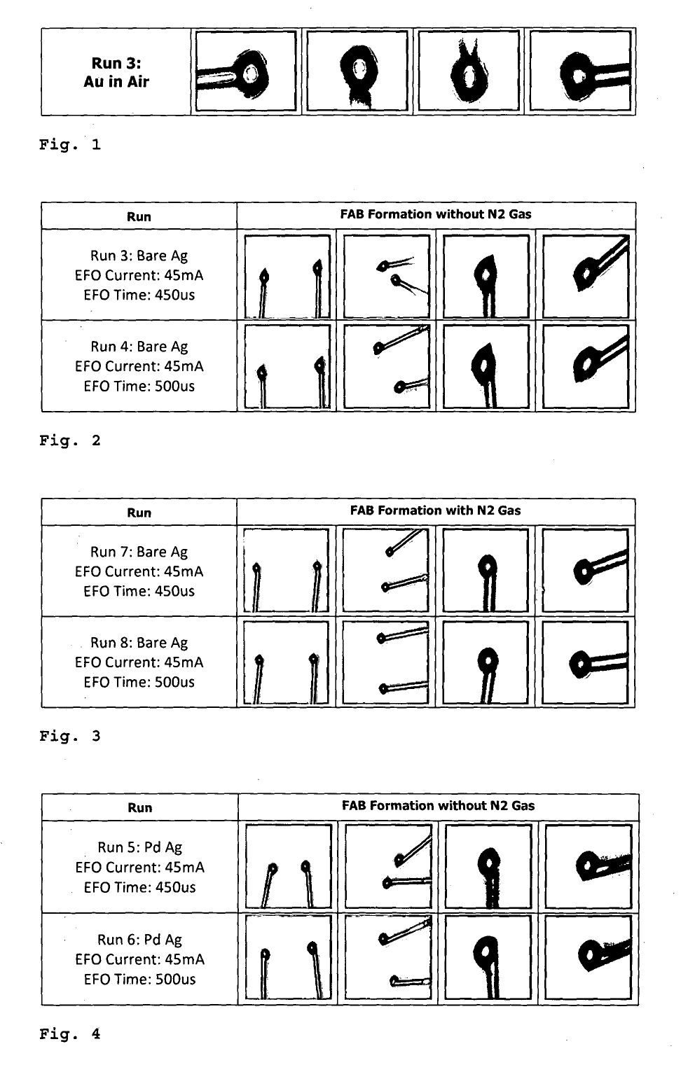

FIG. 1 shows photos of a free air ball formation of an uncoated gold wire (purity ≧99%). The results are perfect spheres formed by the gold wire in an air environment. The photos show the current standard for ball-bonding, i.e. high purity (≧99%) gold wires forming free air ball in air environment. As shown, the resuiting free air balls are spherical, axi-symmetric, smooth and oxide/contaminant free.

FIG. 2 shows photos of a free air ball formation of an uncoated silver wire (purity ≧99%) in air. Two runs were performed, one at an electrical flame off (EFO) time of 450 ρs, the other at an EFO time of 500 ρs. Both resulted in poorly formed free air balls (FABs), the resulting FABs are pointed with a severely distorted shape.

FIG. 3 shows photos of a free air ball formation of an uncoated silver wire (purity ≧99%) in nitrogen gas (N₂). Again, two runs were performed, one at an EFO time of 450 μs, the other at an EFO time of 500 ρs. The results were improved shapes of the FABs. As can be seen, the overall sphericity and axi-symmetry is much improved vs. formation in air; however, it is inconsistent with some pointed tips and off-centered balls.

In the following, two different types of coated bonding wires according to the invention were tested. The first coated wire had a thinner coating made under a longer thermal process, the second coated wire had a thicker coating made under a shorter thermal process. The coating can be applied by many methods, such as: electroplating, electroless plating, vapour deposition, sputtering, conversion coating, thermal decomposition, nanoparticle synthesis.

FIG. 4 shows photos of a free air ball formation of a first palladium coated silver wire according to the invention (purity of the core material ≧99%) in air. The coating was thin, i.e. in the range of 25 to 50 nm, and made during a long thermal process, i.e. around 250° C. for about 30 minutes. For the wires mentioned, the coating method used is thermal decomposition of an organic-metallic compound or a liquid solution containing nano-particles of the coating material. After coating, the palladium coated wire is thermally post-processed, with ball formation attempted in air environment. Again, two runs were performed, one at an EFO time of 450 μs, the other at an EFO time of 500 μs. The palladium coating improves the roundness of the ball somewhat, removing the pointed tip, but not yet perfect.

FIG. 5 shows photos of a free air ball formation of a second palladium coated silver wire according to the invention (purity of the core material ≧99%) in air. The coating was thick(er), i.e. in the range of 100 to 200 nm, using organo-metallic thermal decomposition followed by a further short thermal processing, i.e. at around 250° C. for about 2 seconds. One run was performed at an EFO current of 45 mA and an EFO time of 500 μs. The result is that the thicker coating produces a perfect shape of the FABs in air. The palladium coating improves all aspects of the ball (e.g. sphericity, smoothness and axi-symmetry) to an acceptable level, similar to gold. It was found that the range for coating thickness in the case of Palladium in order to achieve good results is above 50 nm and below 500 nm. A good interval for the coating thickness of Palladium is 50 nm to 200 nm. Another good interval for the coating thickness of Palladium is 50 nm to 100 nm. Another good interval for the coating thickness of Palladium is 100 nm to 200 nm.

Moreover, it was found that the coating thickness varies with the surface tension requirement or characteristic: the higher the surface tension, the less coating thickness is required, the lower the surface tension, the more coating thickness is required. In view of the materials identified as suitable in the context of this invention, this would mean that for Gold a somewhat thicker coating is required than for Palladium in order to achieve the same quality results. Using Platinum and Rhodium as coating material would lead to somewhat thinner coatings than for Palladium. However, a suitable range for all of these materials can be given as 50 nm to 500 nm.

The annealing time of the thermal process also varies with the chosen coating material. A general good range for all materials can be given as 0.1 seconds to 60 seconds, or 0.1 seconds to 40 seconds, or 0.1 seconds to 30 seconds, or 0.1 seconds to 20 seconds, or 0.1 seconds to 10 seconds. Alternatively, the range can be given as 0.5 seconds to 40 seconds, or 1 second to 40 seconds, or 2 seconds to 40 seconds, or 2 seconds to 30 seconds, or 2 seconds to 20 seconds, or 2 seconds to 10 seconds. Again, it was found that the annealing time varies with the selected coating material: the higher the melting point of the selected coating material, the longer the annealing time. This would mean that in case Platinum is used as coating material, the annealing time should be chosen somewhat longer than for Palladium. Rhodium again should be annealed longer than Platinum, whereas Gold should be annealed shorter than Palladium. A range selection for the annealing time of Palladium could be given as 0.1 seconds to 10 seconds.

The person skilled in the art can easily determine appropriate parameter pairs for the coating thickness and the annealing time for a given coating material based on the above findings.

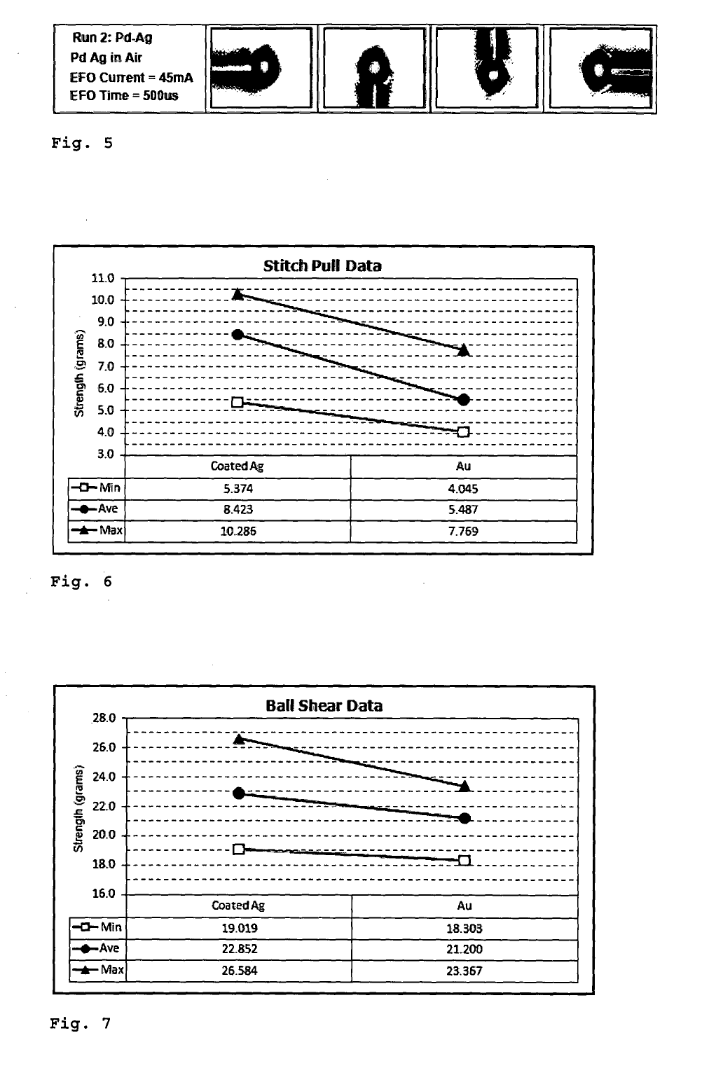

FIG. 6 shows the wire-bonding performance of the stitch bond. The strength of the weld is shown to be equivalent or better than that of the reference gold wire. This indicates that the palladium coating does not add too much hardness or the post-heat treatment cycle does not add too much softness to the overall mechanical properties of the wire. The Pd-coated Ag wire remains soft, allowing it to be squashed and welded easily to the substrate, by the capillary.

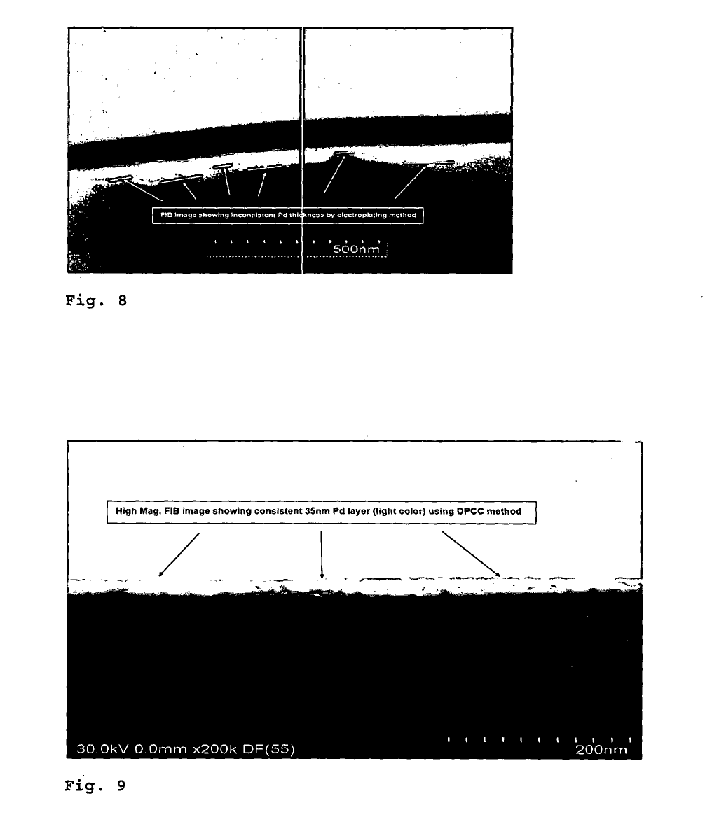

FIG. 7 shows the strength of the bonded ball. The strength of the weld is shown to be greater or equal than that of the reference gold wire.

Additionally, it was measured that the hardness of the palladium coated silver wire bonded ball was comparable to gold wire. This property is important to prevent damage to sensitive chip structures. By contrast, copper wire bonded ball was found to be much harder than gold, silver or coated silver wire.

It was found that the wire-bonding parameters required on the equipment used for bonding the wire (such as power, force and time) were similar to that of the gold wire. This is also important to prevent chip damage.

Coated Copper Wire

Coating Process and Consistency of Coating Thickness

Samples of palladium coated copper wires were prepared using electroplated Pd and the thermal decomposition of organic or nano-metallic Pd precursors. It was found that the accuracy of deposition of coating thickness was far superior using the thermal decomposition method.

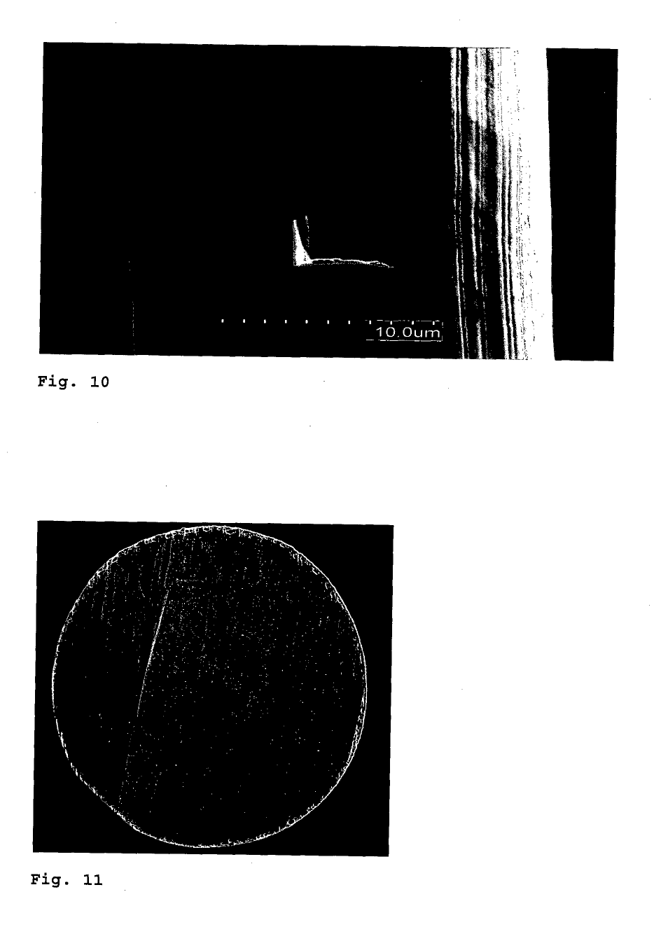

FIG. 8 shows a cross-section of a typical Pd electroplated copper wire with palladium thickness ranging from about 100 nm to 20 nm. FIG. 9 shows a consistent Pd coating using thermal decomposition, ranging from about 30 nm to 40 nm. Further observation of surface of the electroplated Pd—Cu wire (FIG. 10), reveals striations parallel to the axis of the wire, further indicating high and low areas for coating.

Morphology and Diffusion of Pd Coating Layer

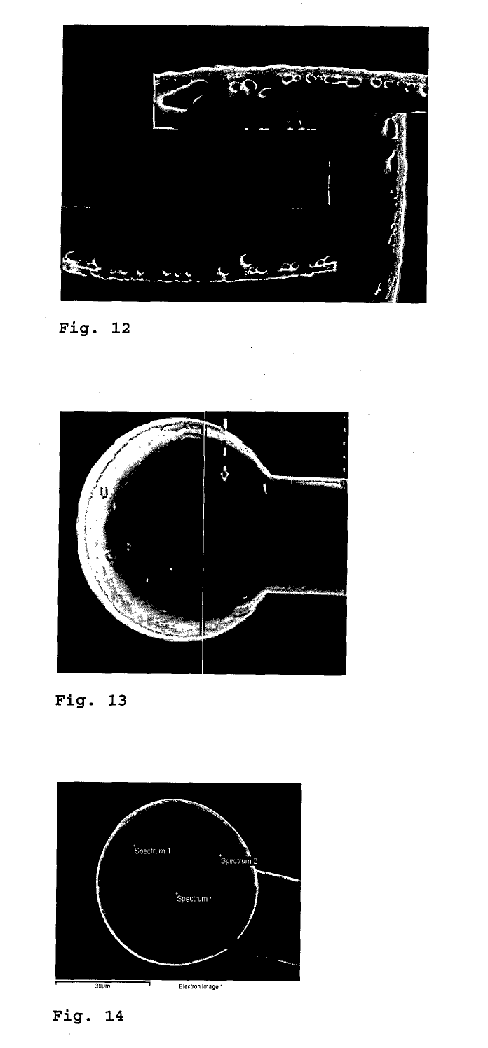

FIGS. 11 and 12 show that the coating structure produced by thermal decomposition contains a macro-porous and nano-porous void layer between the core wire and the coating material and no apparent diffusion between copper metal and palladium.

Free Air Ball of Pd-Coated Copper Bonding Wires

The free air ball of electroplated copper is characterized by non-uniform coverage of palladium in the form of stripes on the copper free air ball surface, as shown in FIG. 13. This is readily explained in relation to diffusion of the thin stripes visible on the axis of wire surface as shown in FIG. 10, previously. During FAB formation, the copper and palladium melt at a very high temperature, which accelerates Pd and Cu diffusion rates, and the relative concentration of metals will attempt to balance to an equilibrium. In the case of electroplated Pd on Cu wire, there are many high peaks and low valleys of Pd initially on the wire. During melting, the low thickness valleys of Pd will diffuse rapidly into the Cu ball itself, leaving the lower hemisphere of the Pd—Cu free air ball exposed with copper alone. This copper exposure will increase galvanic corrosion of the Cu bonded ball-Al bond pad system.

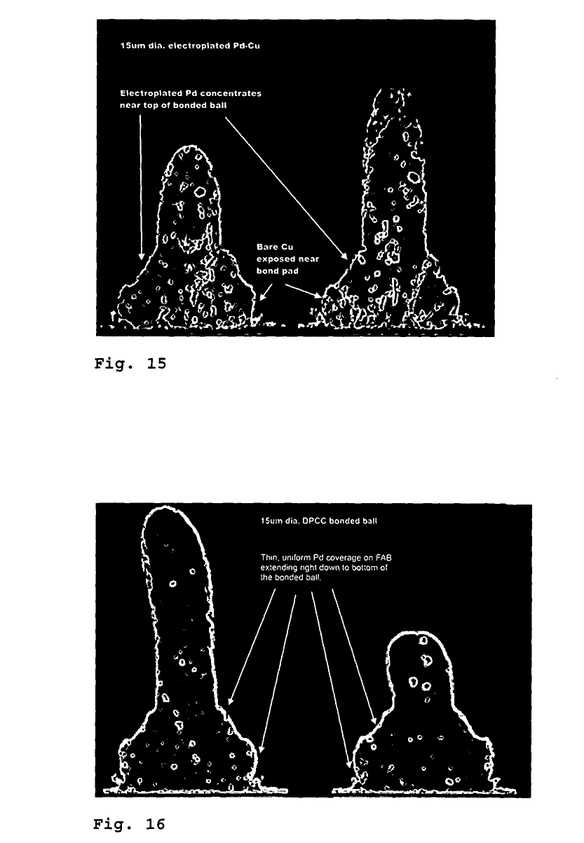

By contrast, EDX analysis of the Pd—Cu wire fabricated by thermal decomposition method reveals full and uniform coverage of the free air ball (FIG. 14), even though the average thickness is relatively low ˜35 nm. This is partially explained by: (a) the void layer impeding diffusion and (b) the uniform thickness of the Pd layer does not create un-equal diffusion rates on the ball surface. The thin, but uniform Pd coverage on the FAB by the thermal decomposition method is further confirmed by a cross-section of the bonded ball (FIG. 16) in comparison to the electroplated method (FIG. 15), where is it seen that coating concentrates near the upper part of the bonded ball, leaving the area where the ball connects to the chip relatively thin or deficient in palladium.

Softness of Free Air Ball for Pd-Coated Copper BondIng Wires

Copper is harder than gold or silver and even though high purity (e.g. 99.9999%) Cu can be made initially as soft as gold, copper has the property that it will become harder (i.e. strain hardened) upon exposure to compressive force and stress.

For semiconductor assembly, this means that when the copper free air ball is pressed down upon the IC chip, it may damage or crack the sensitive circuits below. Thus, for copper-based wires, it is important to reduce the hardness and increase the softness of the bonded ball.

In the depiction of FIG. 17, wires #1 and #2 are coated with palladium using the thermal decomposition method, and wire #3 is the corresponding bare wire and a second group of wires is shown where wires #4 and #5 are the palladium coated wires and wire #6 is the corresponding bare wire.

In both trials, the palladium coated wires were shown to be softer than the corresponding bare wire. This result indicates that diffusion of the palladium into the bulk of the copper free air ball is minimal, as increased diffusion of Pd into Cu would create alloying and resulting harder ball. In the case of Pd—Cu fabricated by the thermal decomposition method, the palladium is remaining on the surface of the free air ball as a shell or skin, while the inner copper FAB core is being annealed during free air ball formation heat sparking.

FIG. 18 compares the bonded ball height of the electroplated Pd—Cu wire versus thermal decomposition coated Pd—Cu wire. For identical initial ball height and same bonding parameters, the thermal decomposition Pd—Cu bonded ball is ‘squashed’ to a lower height (7.2 μm) as compared to the electroplated Pd—Cu ball (9.7 μm). Lower height equates to softer ball. Again, this indicates that the improved softness of the Pd—Cu wire coated by thermal decomposition method as compared to electroplating.

Stitch Bond Performance of Pd-Coated Copper Bonding Wires

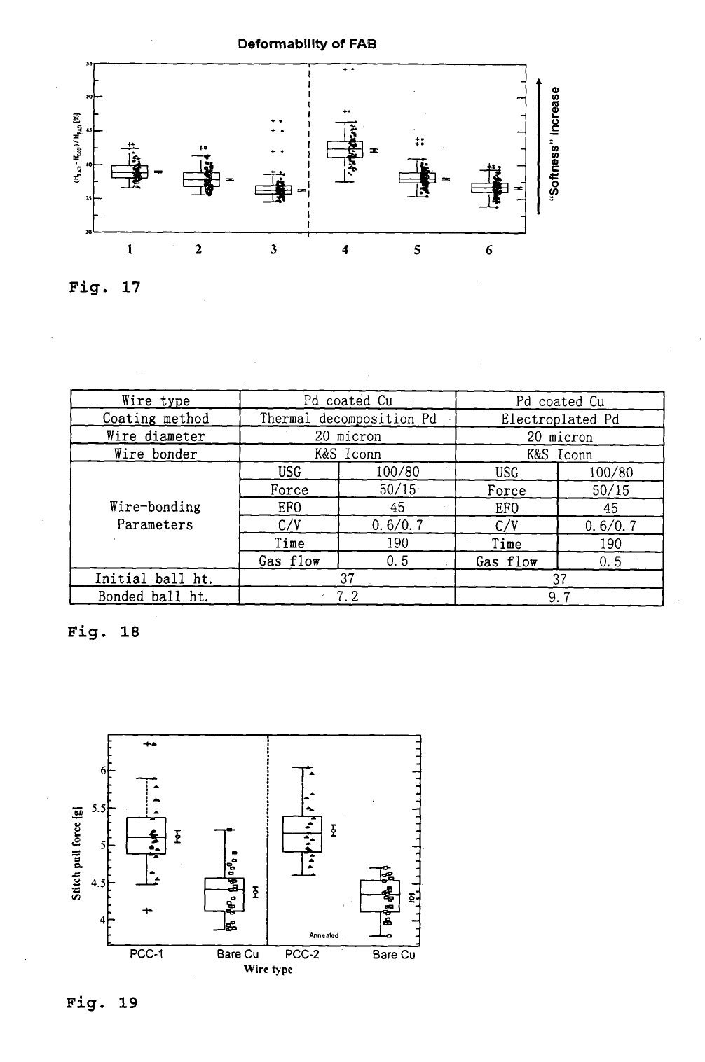

FIG. 19 shows the result of stitch pull testing, i.e., strength of the second bond (also called ‘stitch bond’) for the palladium coated copper wires (PCC-1, PCC-2) as compared to bare copper wires upon which they were coated using thermal decomposition techpique. It is readily apparent that palladium coating improves the strength of the stitch bond.

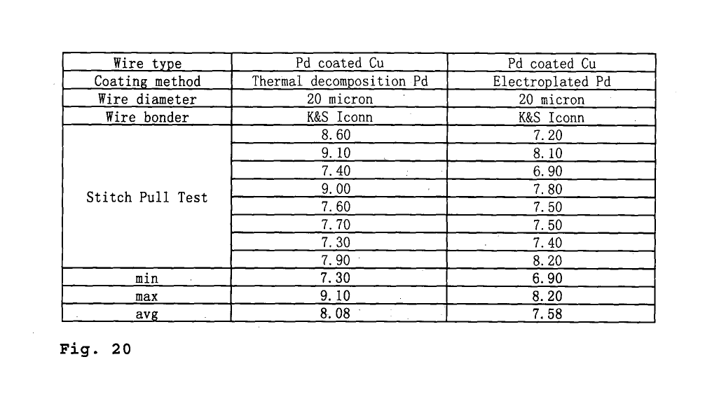

FIG. 20 compares the stitch bond pull strength of Pd—Cu coated using thermal decomposition method (average=8.08 g) versus electroplated method (average=7.58 g), indicating a significant increase (0.5 g) for the thermal decomposition method.

1. A bonding wire comprising a core wire generally surrounded by a coating, wherein the core wire is made generally of silver or a silver alloy, and wherein the coating material is selected from one or more of: gold, palladium, platinum, rhodium.

2. A bonding wire comprising a core wire generally surrounded by a coating, wherein the core wire is made generally of copper or a copper alloy, and wherein the coating material is selected from one or more of: palladium, platinum, rhodium, iridium, ruthenium.

3. A bonding wire comprising a core wire generally surrounded by a coating, wherein the core wire is made generally of silver or a silver alloy, and wherein the coating material is selected from a group of materials with the following characteristics: (1) the materials' melting temperature is higher than the melting temperature of the core wire material, respectively; (2) the materials' molten surface tension is higher than that of the core wire material, respectively; (3) the materials show a high resistance to oxide formation between the melting temperature of the core wire material and the melting temperature of the respective material itself; and (4) the coating material has the additional characteristic that the material's melting temperature is lower than the boiling temperature of the core wire material.

4. A bonding wire comprising a core wire generally surrounded by a coating, wherein the core wire is made generally of copper or a copper alloy, and wherein the coating material is selected from a group of materials with the following characteristics: (1) the materials' melting temperature is higher than the melting temperature of the core wire material, respectively; (2) the materials' molten surface tension is higher than that of the core wire material, respectively; (3) the materials show a high resistance to oxide formation between the melting temperature of the core wire material and the melting temperature of the respective material itself; and (4) the coating material has the additional characteristic that the material's melting temperature is lower than the boiling temperature of the core wire material.

5. The bonding wire according to any one of claims 1 to 4, wherein the core wire has an overall diameter between 10 μm and 100 μm.

6. The bonding wire according to any one of claims 1 to 5, wherein the thickness of the coating material is between 10 nm and 500 nm.

7. The bonding wire according to any one of claims 1 to 5, wherein the ratio of the difference between the maximum thickness of the coating material and the minimum thickness of the coating material divided by the average thickness of the coating material is less than 20%, measured radially along the length of the wire.

8. The bonding wire according to any one of claims 1 to 5, wherein the weight percentage of the coating material is between 0.5% and 4% of the total bonding wire.

9. The bonding wire according to any one of claims 1 to 5, wherein the coating is comprised of coating material and nanoporous voids with mean diameter less than 100 nm.

10. A process for manufacturing a bonding wire, comprising the steps of:
providing a core wire of silver or a silver alloy;
depositing a coating on the core wire, the coating material being selected from one or more of: gold, palladium, platinum, rhodium.

11. A process for manufacturing a bonding wire, comprising the steps of:
providing a core wire of copper or a copper alloy;
depositing a coating on the core wire, the coating material being selected from one or more of: palladium, platinum, rhodium, iridium, ruthenium.

12. A process for manufacturing a bonding wire, comprising the steps of:
providing a core wire of silver or a silver alloy;
depositing a coating on the core wire, the coating material being selected from a group of materials with the following characteristics: (1) the materials' melting temperature is higher than the melting temperature of the core wire material, respectively; (2) the materials' molten surface tension is higher than that of the core wire material, respectively; (3) the materials show a high resistance to oxide formation between the melting temperature of the core wire material and the melting temperature of the respective material itself; and the material's melting temperature is lower than the boiling temperature of the core wire material.

13. A process for manufacturing a bonding wire, comprising the steps of:
providing a core wire of copper or a copper alloy;
depositing a coating on the core wire, the coating material being selected from a group of materials with the following characteristics: (1) the materials' melting temperature is higher than the melting temperature of the core wire material, respectively; (2) the materials' molten surface tension is higher than that of the core wire material, respectively; (3) the materials show a high resistance to oxide formation between the melting temperature of the core wire material and the melting temperature of the respective material itself; and the material's melting temperature is lower than the boiling temperature of the core wire material.

14. The process of any one of claims 10 to 13, wherein depositing of the coating material is made by one or more of electroplating, electroless plating, immersion plating, vapor deposition, sputtering, organo-metallic decomposition, metal-salt decomposition, metal-ligand decomposition, thermal spray, conversion coating, thermal decomposition, pyrolysis, thermolysis, ultraviolet irradiation and decomposition or nano-particle sintering.

15. The process of any one of claims 10 to 13, wherein depositing of the coating material is made by one or more of thermal decomposition of an organic-metallic compound, metal salt or metal-ligand complex.

16. The process of any one of claims 10 to 13, wherein depositing of the coating material is made by thermal sintering of metal particles of less than 100 nm of said coating material.

17. The process of any one of claims 10 to 16, further comprising at least one step of a post-treatment of the deposit film coating by thermal processing.

18. The process of claim 17, wherein the thermal processing is done in the temperature range of 200° C. to 600° C.

19. The process of claim 17, wherein the thermal processing is done in the temperature range of 250° C. to 600° C.

20. The process of claim 17, 18 or 19, wherein the duration of thermal processing is done for a minimum duration of 0.1 seconds and maximum duration of 10 seconds.

21. The process of any one of claims 17 to 20, wherein the thermal processing is performed in a gas environment such as: argon, hydrogen, nitrogen, helium, neon, oxygen and/or mixtures thereof, including standard air environment.
